(19) United States
(12) Patent Application Publication
(10) Pub. No.: US 2014/0117469 A1
(43) Pub. Date: May 1, 2014

(54) TSV-MEMS COMBINATION

(71) Applicant: TEXAS INSTRUMENTS INCORPORATED, Dallas, TX (US)

(72) Inventors: YOSHIMI TAKAHASHI, BEPPU-CITY (JP); KOHICHI KUBOTA, BEPPU-CITY (JP)

(73) Assignee: Texas Instruments Incorporated, Dallas, TX (US)

(21) Appl. No.: 13/661,712

(22) Filed: Oct. 26, 2012

(51) Int. Cl. H01L 29/84; H01L 21/82

(52) U.S. Cl. 257/415; 438/51; 257/E29.324; 257/E21.602

(57) ABSTRACT

A through-substrate via (TSV)-MEMS combination includes a TSV die including a substrate and a plurality of TSVs which extend of a full thickness of the substrate. The TSV die includes a top side surface including circuitry and top side bonding pads thereon, a bottom side surface including bottom side bonding features thereon, and a through-hole through the full thickness of the substrate. A microelectromechanical systems (MEMS) die having a floating sensing structure including solder balls thereon is bound to the top side bonding pads or bottom side bonding features of the TSV die. A layer of adhesive material is surrounding the solder balls, which can provide a sealant ring for the TSV-MEMS bonds.

### FIELD

Disclosed embodiments relate to through silicon via (TSV)-Microelectromechanical systems (MEMS) combinations.

### BACKGROUND

CMOS microelectromechanical systems (MEMS) devices are the bonded combination of an electro-mechanical system (MEMS) die and CMOS integrated circuit (IC) die. The CMOS IC die is generally a through silicon via (TSV) die. The MEMS die has at least one MEMS device including a vibration catching port (e.g., a floating structure such as a thin membrane) for sensing, and the sensing signals generated are amplified and generally filter by circuitry on the TSV die.

One example of a MEMS device is a micro-inertial sensor. Traditional packaging of MEMS devices uses wire bonding and injection molding to protect the bonding area of the device. This type of packaging creates a relatively large overall size.

### SUMMARY

Disclosed embodiments include through-substrate via (TSV)-MEMS combinations, and method of assembling TSV-MEMS combinations. One method embodiment comprises providing a TSV substrate (e.g., a TSV wafer) including a plurality of TSV die. The TSV die each include a plurality of TSVs which extend of a full thickness of the TSV substrate. A top side surface of the TSV die (typically a semiconductor surface) includes circuitry and top side bonding pads thereon, and a bottom side surface includes bottom side bonding features thereon, such as a redirect layer (RDL) including land grid array (LGA) pads or protruding TSV tips. The bottom side or top side surface of the TSV substrate is on a support, such attached to a heat resistant tape or on a support plate. The TSV substrate is dry etched to form at least one through-hole (an acoustic hole) through its full thickness. A patterned layer of adhesive material is formed on the exposed top side surface or bottom side surface (exposed surface) of the TSV die.

A MEMS wafer having a plurality of MEMS die each having floating sensing structures including solder balls thereon is bound to the exposed surface of the plurality of TSV die, wherein the solder balls are aligned to the exposed top side bonding pads or bottom side bonding features of the TSV die. The support is then removed, and singulation of at least the MEMS wafer separates the MEMS wafer into the plurality of MEMS die to form a plurality of disclosed TSV-MEMS combinations.

### BRIEF DESCRIPTION OF THE DRAWINGS

Reference will now be made to the accompanying drawings, which are not necessarily drawn to scale, wherein:

FIG. 1 is a flow chart that shows steps in an example method for forming TSV-MEMS combinations where the TSV die have a through-hole, according to an example embodiment.

FIGS. 2A-2E are a series of simplified cross section depictions showing assembly process progression for an example assembly process including FIG. 2A showing a TSV die of a TSV substrate (e.g., wafer) attached to a tape; FIG. 2B is a simplified cross section depiction showing the TSV die singulated and having a through-hole after dry etching the TSV substrate and opening scribe lines which singulate the TSV die; FIG. 2C is a simplified cross section depiction showing patterned adhesive material on the top side surface of the TSV die after forming a patterned layer of adhesive material; FIG. 2D is a simplified cross section depiction showing patterned adhesive material on the solder balls of the MEMS die after forming a patterned layer of adhesive material which is an alternative to the embodiment shown in FIG. 2C, and FIG. 2E is a simplified cross section depiction showing a top chuck bonding a MEMS wafer having a plurality of MEMS die each having a floating sensing structure having solder balls onto the top side surface of the TSV die.

FIG. 3A is a top view depiction of a TSV die having grooves on its top surface that help shape the adhesive material (not shown) when dispensed to provide a hermetic sealing ring for the TSV-MEMS combination following reflow, according to an example embodiment.

FIG. 3B is a top view depiction of a MEMS die with grooves on its top surface that help to shape the sealing according to an example embodiment. The MEMS die is shown including an optional through-hole.

FIG. 3C is a cross sectional depiction of an example TSV-MEMS combination comprising a TSV die bound to a MEMS die showing the adhesive material surrounding the solder balls providing a sealing ring during joint process and/or after cure, according to an example embodiment.

FIG. 3D is a cross sectional depiction of an example TSV-MEMS combination comprising a TSV die having protruding TSV tips on its bottom side with its top side bond pads bound to solder balls on a MEMS die showing the adhesive material surrounding the solder balls providing a sealing ring during joint process and/or after cure, according to an example embodiment.

FIG. 3E is a cross sectional depiction of an example TSV-MEMS combination comprising a TSV die having protruding TSV tips on its bottom side, where the TSV tips are bound to solder balls on a MEMS die showing the adhesive material surrounding the solder balls providing a sealing ring during joint process and/or after cure, according to an example embodiment.

FIG. 4A is a cross sectional depiction of a TSV-MEMS combination/package including the TSV-MEMS combination shown in FIG. 3C bound to a package substrate, according to an example embodiment.

FIG. 4B is a cross sectional depiction of a TSV-MEMS combination/package including a TSV-MEMS combination which modifies the TSV-MEMS combination shown in FIG. 3C by having the MEMS die include an optional through-hole, which is bound to a package substrate that itself has a through-hole, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Disclosed embodiments include TSV-MEMS combinations and assembly methods for forming TSV die to MEMS die interconnections. The TSV-MEMS combinations may be formed by die-to-wafer methods where the TSV substrate (e.g., wafer) is singulated before bonding, or by wafer-to-wafer methods. Without an optional package substrate, disclosed TSV-MEMS combinations may be considered a Wafer Chip Scale Package (WCSP). The TSV die include an acoustic through-hole referred to herein as a through-hole, and the MEMS die has a floating structure for sensing that may optionally include a through-hole. Disclosed TSV-MEMS combinations may optionally be mounted onto a package substrate (e.g., a printed circuit board (PCB) or mother board).

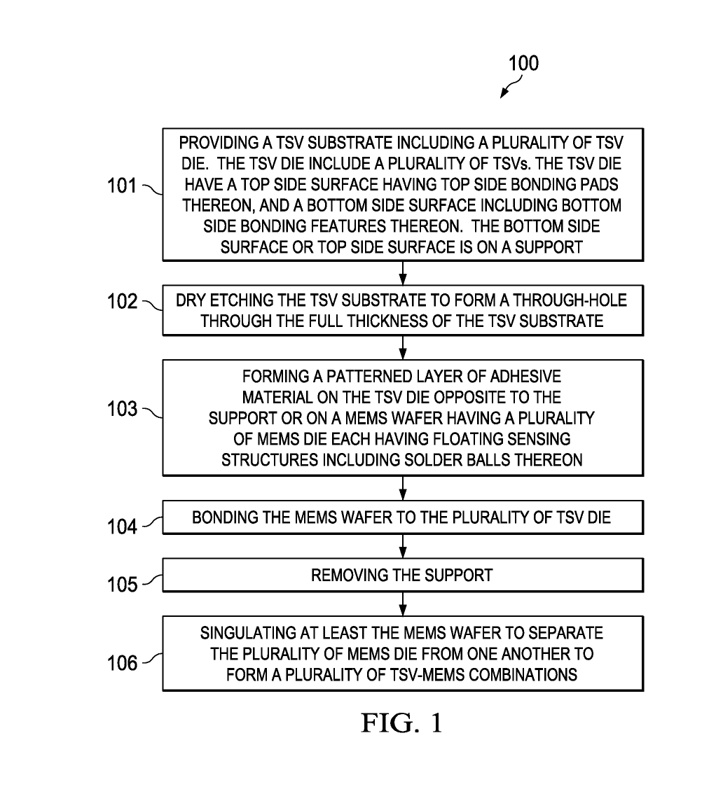

FIG. 1 is a flow chart that shows steps in an example assembly method 100 for forming TSV-MEMS combinations, according to an example embodiment. Step 101 comprises providing a TSV substrate (e.g., a wafer, such as a silicon wafer) including a plurality of TSV die. The TSV die include a plurality of TSVs which extend of a full thickness of the TSV substrate. The TSV die have a top side surface (e.g., silicon surface) which includes circuitry (e.g., PMOS and NMOS transistors) and top side bonding pads thereon, and a bottom side surface including bottom side bonding features thereon.

The bottom side bonding features can comprise land grid array (LGA) pads as part of a redirect layer (RDL) with some of the LGA pads connected to TSVs, or where the TSVs include protruding TSV tips. The bottom side surface or top side surface of the TSV die is on a support. The support can comprise a tape (e.g., heat resistant dicing tape) or a support plate.

TSV substrates (e.g., TSV wafers) may be prepared by providing a wafer having embedded metal filled vias and top side bonding pads thereon, attaching the TSV wafer to a carrier wafer, and thinning the wafer (generally including backgrinding) to expose previously embedded metal filled vias to form TSVs.

Step 102 comprises dry etching the TSV substrate to form a through-hole through the full thickness of the TSV substrate. Dry etching includes plasma etching and reactive ion etching (RIE). For die-to-wafer (D2W) embodiments, step 102 also singulates the plurality of TSV die. Step 103 comprises forming a patterned layer of adhesive material on the TSV die opposite to the support or on a MEMS wafer having a plurality of MEMS die each having floating sensing structures including solder balls thereon. Step 104 comprises bonding the MEMS wafer to the plurality of TSV die. The solder balls are aligned to provide an interconnection to the top side bonding pads for top side bonding to the TSV die or bottom side bonding features for bottom side bonding to the TSV die.

The MEMS die can include structures formed using conventional CMOS fabrication processing and may include a plurality of elements formed on metal, polysilicon, dielectric, and/or other materials. The MEMS die can be formed using typical processes used in CMOS fabrication, for example, photolithography, ion implantation, etching processes (e.g., wet etch, dry etch), deposition processes, plating processes, etc. The floating sensing structures can provide a variety of sensors, such as a motion sensor (e.g., a gyroscope, an accelerometer, etc.).

Step 105 comprises removing the support from the TSV die. Method 100 can further comprise reflowing the adhesive material after bonding (step 104), wherein the adhesive material after reflow provides a sealant ring for the plurality of said TSV-MEMS combinations. Step 106 comprises singulating at least the MEMS wafer to separate the plurality of MEMS die from one another to form a plurality of disclosed TSV-MEMS combinations.

There are three example embodiments for assembly method 100 described herein referred to as assembly “process 1”, “process 2”, and “process 3”. Assembly process 1 forms the TSV die's through-hole after debonding the thinned TSV substrate (e.g., TSV wafer) from a carrier wafer used for thinning the TSV substrate and exposing embedded metal filled vias to form the TSVs, and laminating the thinned TSV substrate onto a tape. Assembly process 2 forms the TSV die's through-hole after debonding the thinned TSV substrate from a carrier wafer used for thinning the TSV substrate and forming the TSVs, and mounting the thinned TSV substrate on a support plate which may use a vacuum for holding the thinned TSV substrate. Assembly process 3 forms the TSV die's through-hole after substrate thinning to form the TSVs, but before debonding of the carrier wafer, where a support plate is added under the carrier wafer before bonding the MEMS wafer to the TSV die, and the support plate and carrier wafer are removed after bonding the MEMS wafer to the TSV die.

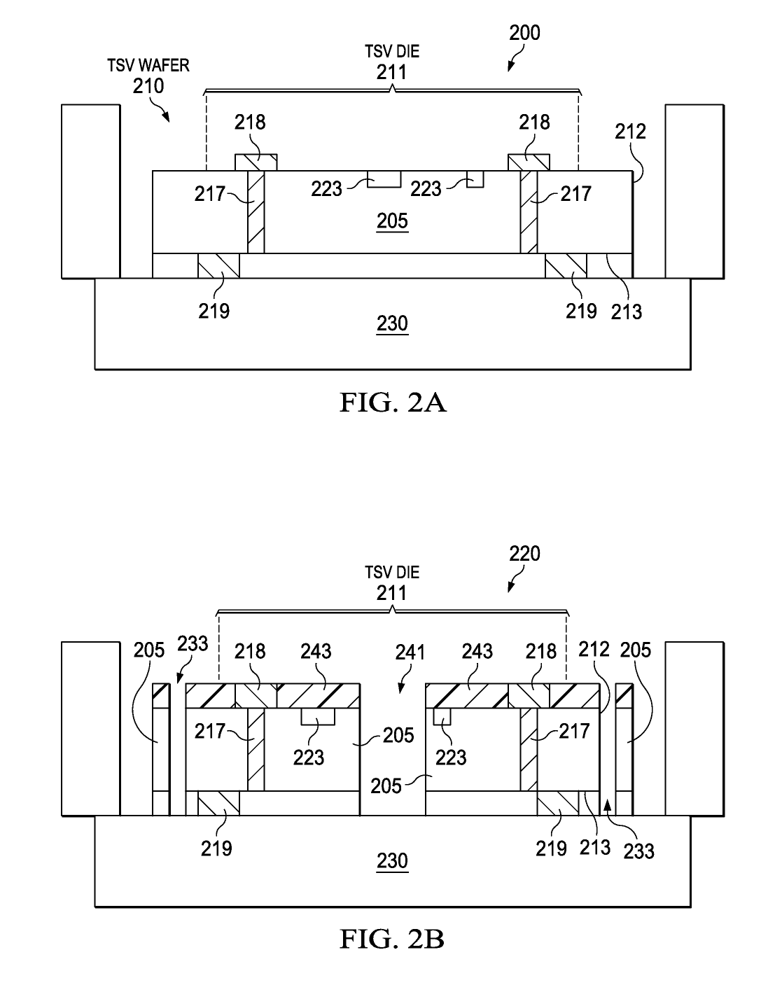

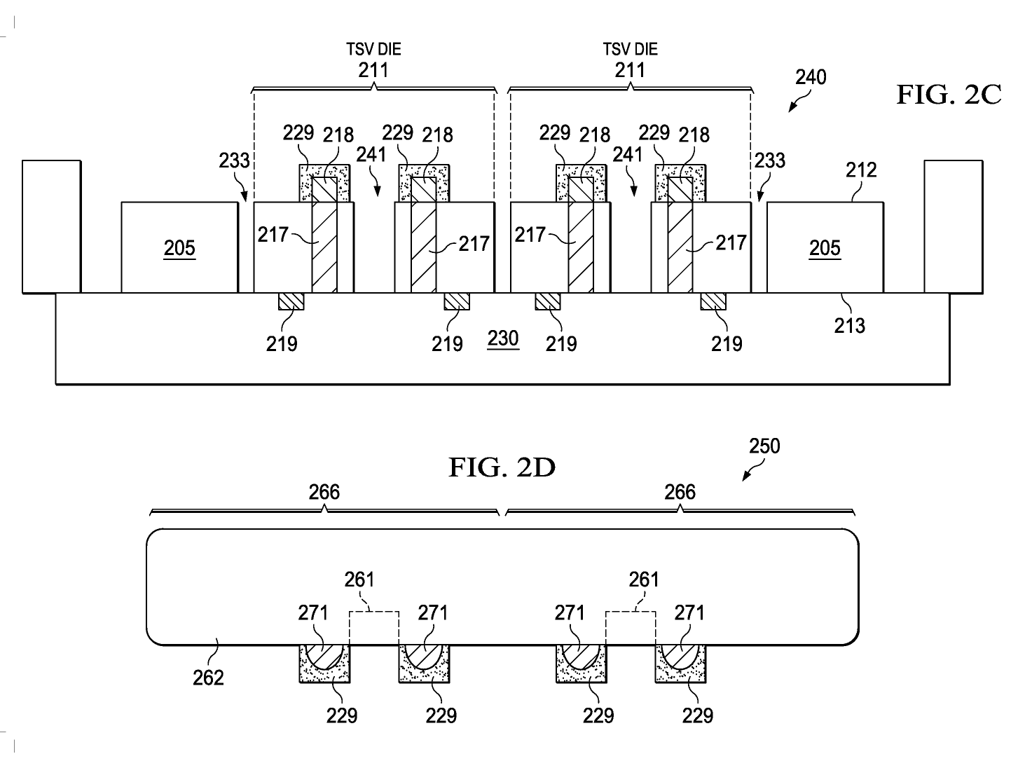

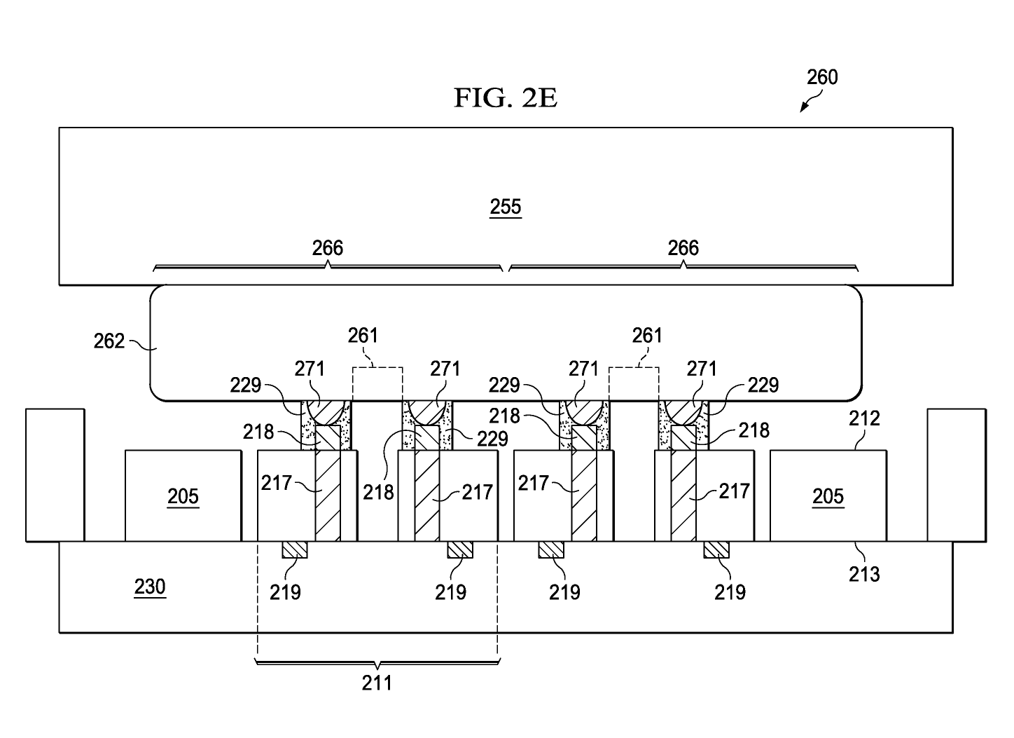

Assembly process 1 is described with reference to FIGS. 2A-E. FIG. 2A is a simplified cross section depiction 200 showing a TSV die 211 of a TSV wafer 210 including a substrate 205 attached to a tape 230. The tape 230 can comprises a heat resistant tape. The TSV die 211 includes a plurality of TSVs 217 which extend a full thickness of the substrate 205/TSV wafer 210, which may be about 75 μm to 125 μm (e.g., 100 μm) thick.

TSVs 217 may comprise a metal core such as copper and generally include an outer dielectric liner and barrier layer (not shown). The TSV die 211 includes a top side surface 212 which is generally a semiconductor surface including circuitry 223 and top side bonding features shown as top side bond pads 218 which couple to nodes on the TSV die 211, including to certain TSVs 217. Circuitry 223 includes transistors (e.g., NMOS and/or PMOS transistors) and circuitry associated with the transistors, such as resistors and capacitors. Interconnects are not shown for simplicity.

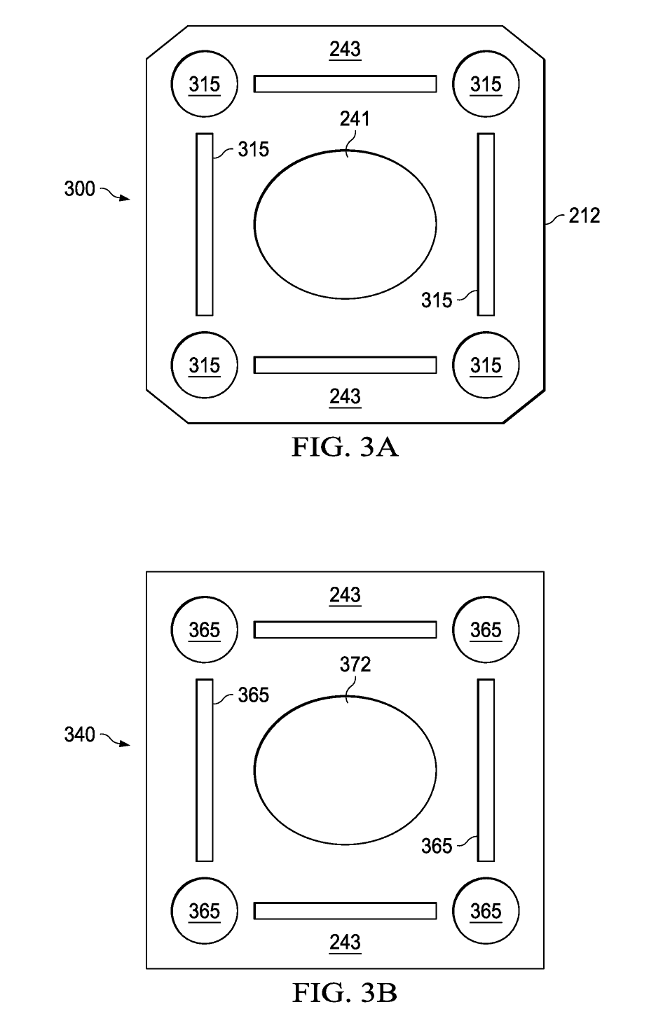

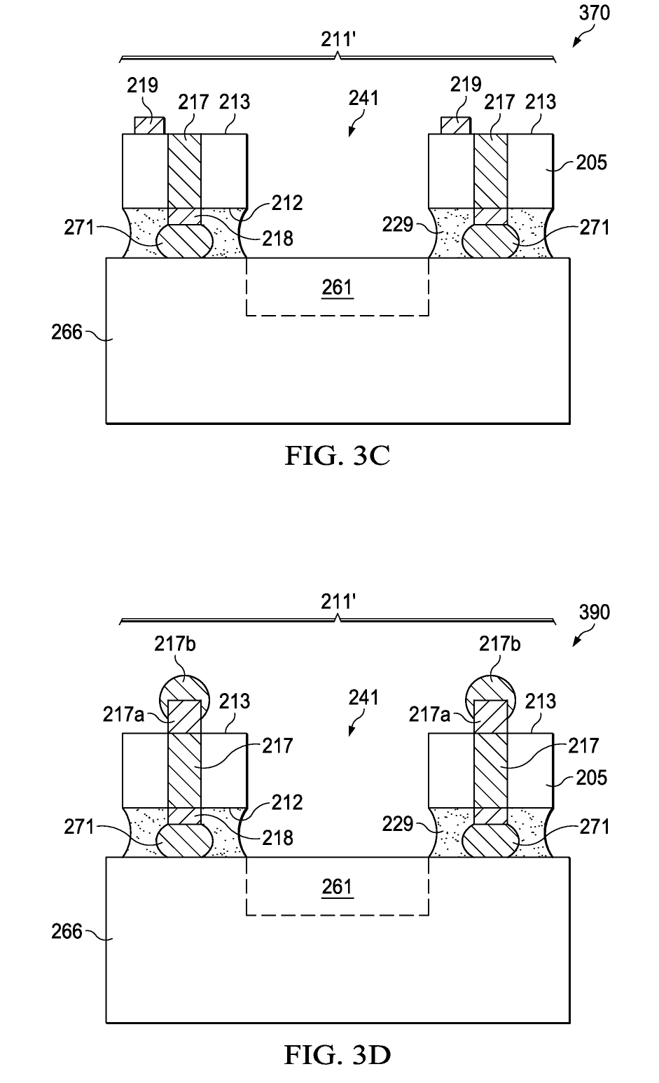

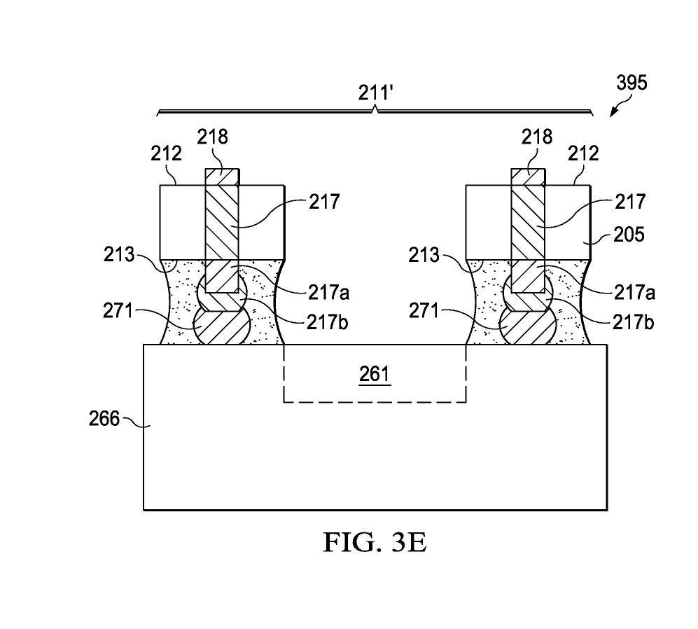

The TSV die 211 includes a bottom side surface 213 shown including a redirect layer (RDL) with land grid array (LGA) pads 219 of the RDL shown. Although not shown, the TSVs 217 may include protruding tips (e.g., 5 to 15 μm long) instead of an RDL (see FIG. 3D described below). The LGA pads 219 on the bottom side surface 213 of the TSV die 211 is shown attached to the tape 230.

FIG. 2B is a simplified cross section depiction 220 showing the TSV wafer 210 after dry etching for singulation into TSV die 211 by forming open scribe lines 233 and formation of a through-hole 241. In a typical embodiment, a masking layer 243, such as a polyimide, solder resist or other organic layer, is patterned as shown to allow selectively dry etching (e.g., plasma etching or reactive-ion etching (RIE)) to form the open scribe lines 233 and through-hole 241 while leaving other regions on the TSV die 211 unaffected (not etched). Solder resist and photoresist are materials which may be readily removed by ashing. The through-hole 241 is generally centrally located on the TSV die 211 as shown, although centering of the through-hole 241 is not required.

The through-hole 241 for the TSV die 211 and optional through-hole for the MEMs die (described below) due to being formed by dry etching have at least one of (i) substantially vertical sidewalls, which can be distinguished over wet etch formed though-holes which have curved walls because the vertical wet etch rate is approximately equal to the horizontal wet etch rate, and (ii) a sidewall roughness <3 nm root mean square (RMS). As used herein, “substantially vertical sidewalls” refers to sidewall profiles of 90°±5.

FIG. 2C is a simplified cross section depiction 240 showing patterned adhesive material 229 on the TSV die 211 after forming a patterned layer of adhesive material on the top side surface 212 of the TSV die 211. The adhesive material 229 can be screen printed, and in one embodiment can be a B-stage adhesive which includes solvent as printed. FIG. 2D is a simplified cross section depiction 250 showing patterned adhesive material 229 on the solder balls 271 of the MEMS die 266 after forming a patterned layer of adhesive material, which is an alternative to the embodiment shown in FIG. 2C.

A B-stage adhesive is defined as an intermediate stage in the reaction of certain thermosetting resins in which the materials soften when heated and swell when in contact with certain liquids, but may not entirely fuse or dissolve. The resin in an uncured thermosetting adhesive is usually in this stage. These adhesives are dispensed or applied to one substrate in a fashion similar to traditional epoxy pastes. After dispensing, the adhesives are exposed to a specified thermal regime designed to evolve a majority of the solvent from the material without significantly advancing the crosslinking of the resin. B-staging the adhesive permits the adhesive and substrate construction to be “staged” prior to the bonding process, which can reduce process bottlenecks associated with traditional thermosetting pastes.

FIG. 2E is a simplified cross section depiction 260 showing a top chuck 255 while bonding a MEMS wafer 262 having a plurality of MEMS die 266 each having a floating sensing structure 261 coupled to solder balls 271 to the top side bond pads 218 on the top side surface 212 of the TSV die 211. Top chuck 255 can be used for compression bonding. At this point in the process, a tentative (initial) adhesion/bond is created between solder balls 271 and top side bond pads 218. As described above, the tape 230 can then be removed, followed by singulation of the MEMS wafer to form a plurality of disclosed TSV-MEMS combinations. The final adhesive material 229 shape can be designed to surround the solder balls 271 and provide a hermetic seal during joint process and/or after cure.

FIG. 3A is a top view depiction of an example TSV die 300 having grooves 315 on its top side surface 212 to help shape the adhesive material 229 (not shown) when dispensed to provide a sealing ring for the TSV-MEMS combination following reflow. Grooves 315 are formed in regions lacking the masking layer 243, such as a polyimide, so that the passivation layer below the masking layer 243 is exposed in the grooves 315.

FIG. 3B is a top view depiction of a MEMS die 340 with grooves 365 on its top surface to shape the sealing material. Grooves 365 may be formed analogous to grooves 315 described relative to TSV die 300 in FIG. 3A. MEMS die 340 is shown including an optional through-hole 372.

FIG. 3C is a cross sectional depiction of an example TSV-MEMS combination 370 comprising a TSV die 211′ bound to MEMS die 266 showing the adhesive material 229 surrounding the solder balls 271 which can become a sealing ring during joint process and/or after cure. FIG. 3D is a cross sectional depiction of an example TSV-MEMS combination 390 comprising a TSV die 211′ having protruding TSV tips 217a on its bottom side with its top side bond pads 218 bound to solder balls 271 on a MEMS die 266 showing the adhesive material 229 surrounding the solder balls 271 providing a sealing ting during joint processing and/or after cure, according to an example embodiment. TSV tips 217a protrude from the bottom side surface 213 of the TSV die 211′ generally 5 to 15 μm, and are shown including metal tips 217b that may comprise metals such as nickel.

FIG. 3E is a cross sectional depiction of an example TSV-MEMS combination 395 comprising a TSV die 211′ having protruding TSV tips 217a having metal tips 217b on its bottom side 213, where the metal tips 217b of TSV tips 217a are bound to solder balls 271 on a MEMS die 266 showing the adhesive material 229 surrounding the solder balls 271 providing a sealing ring during joint processing and/or after cure, according to an example embodiment. In another embodiment (not shown) the TSV die 211′ has a bottom side RDL layer including LGA pads that are bound to solder balls 271 on the MEMS die 266.

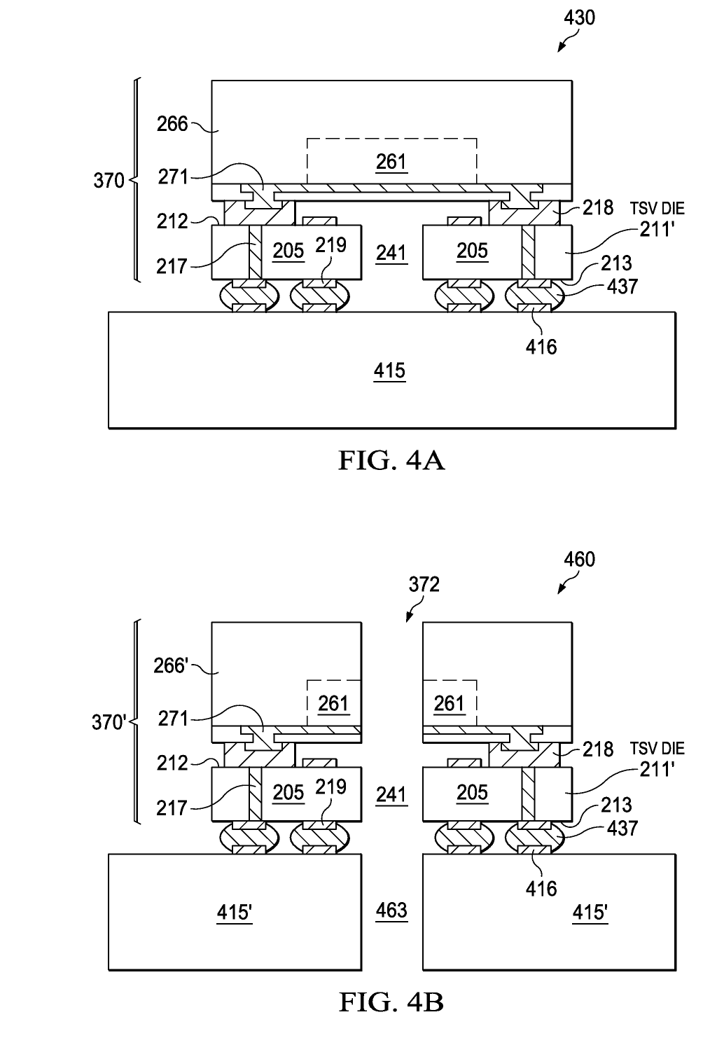

FIG. 4A is a cross sectional depiction of a TSV-MEMS combination/package 430 including the TSV-MEMS combination 370 shown in FIG. 3C bound to a package substrate 415, such as a polymer or ceramic substrate, for example a printed circuit board (PCB). The TSV die 211′ has a bottom side RDL layer including LGA pads 219 bound to pads 416 on the package substrate 415 by solder 437. In one embodiment the package substrate is a customer's mother board (e.g., such as an FR4 (epoxy fiberglass laminate) mother board).

FIG. 4B is a cross sectional depiction of a TSV-MEMS combination/package 460 including TSV-MEMS combination 370′ which modifies TSV-MEMS combination 370 shown in FIG. 3C by having the MEMS die shown as 266′ including an optional through-hole 372, bound to a package substrate 415′ that has a through-hole 463.

Disclosed embodiments can be integrated into a variety of assembly flows to form a variety of different semiconductor integrated circuit (IC) devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A through-substrate via microelectromechanical systems (TSV)-MEMS combination, comprising:
a TSV die including a substrate and a plurality of TSVs which extend a full thickness of said substrate, a top side surface including circuitry and top side bonding pads thereon, and a bottom side surface including bottom side bonding features thereon, and a through-hole through said full thickness of said substrate;
a microelectromechanical systems (MEMS) die having a floating sensing structure including solder balls thereon bound to said TSV die, wherein said solder balls are bonded to said top side bonding pads or said bottom side bonding features, and
a layer of adhesive material surrounding said solder balls.

2. The TSV-MEMS combination of claim 1, wherein said top side bonding pads on said top side surface are bound to said solder balls of said MEMS die.

3. The TSV-MEMS combination of claim 1, wherein said bottom side bonding features on said bottom side surface are bound to said solder balls of said MEMS die.

4. The TSV-MEMS combination of claim 1, wherein said bottom side bonding features comprise a redirect layer (RDL) having land grid array (LGA) pads.

5. The TSV-MEMS combination of claim 1, wherein said plurality of TSVs include protruding TSV tips, and wherein said bottom side bonding features comprise said protruding TSV tips.

6. The TSV-MEMS combination of claim 1, wherein said adhesive material comprises an epoxy.

7. The TSV-MEMS combination of claim 1, wherein said adhesive material provides underfill and a sealant ring for said TSV-MEMS combination.

8. The TSV-MEMS combination of claim 1, wherein said MEMS die includes a through-hole.

9. The TSV-MEMS combination of claim 1, further comprising a package substrate, wherein said TSV-MEMS combination is bonded to said package substrate.

10. The TSV-MEMS combination of claim 1, wherein said top side surface includes a plurality of grooves, and wherein said layer of adhesive material extends over said plurality of grooves.

11. The TSV-MEMS combination of claim 1, wherein said substrate comprises silicon and said plurality of TSVs comprise copper.

12. A method of assembling through-substrate via (TSV)-MEMS combinations, comprising:
providing a TSV substrate including a plurality of TSV die, said TSV die including a plurality of TSVs which extend of a full thickness of said TSV substrate, a top side surface including circuitry and top side bonding pads thereon, and a bottom side surface including bottom side bonding features thereon, wherein said bottom side surface or said top side surface is on a support;
dry etching said TSV substrate form a through-hole through said full thickness of said TSV substrate,
forming a patterned layer of adhesive material on said TSV die opposite to said support;
bonding a MEMS wafer having a plurality of MEMS die each having floating sensing structures including solder balls thereon to said plurality of TSV die,
removing said support, and
singulating at least said MEMS wafer to separate said plurality of MEMS die and form a plurality of said TSV-MEMS combinations.

13. The method of claim 12, wherein said dry etching comprises plasma etching.

14. The method of claim 12, wherein said adhesive material comprises a B-stage adhesive.

15. The method of claim 12, wherein said dry etching further provides singulation of said TSV substrate to separate said plurality of TSV die.

16. The method of claim 12, further comprising reflowing said adhesive material after said bonding, wherein after said reflowing said adhesive material provides a sealant ring for said plurality of said TSV-MEMS combinations.

17. The method of claim 12, wherein said plurality of MEMS die include a through-hole.

18. The method of claim 12, wherein after said singulating, further comprising bonding said TSV-MEMS combination to a package substrate.

19. The method of claim 12, wherein said top side surface includes a plurality of grooves.

20. The method of claim 12, wherein said TSV substrate comprises silicon and said plurality of TSVs comprise copper.
